(19) United States
(12) Patent Application Publication
(10) Pub. No.: US 2019/0085207 A1
(43) Pub. Date: Mar. 21, 2019

(54) POLISHING COMPOSITION FOR OBJECT TO BE POLISHED HAVING METAL-CONTAINING LAYER

(71) Applicant: FUJIMI INCORPORATED, Kiyosu-shi, Aichi (JP)

(72) Inventors: Shogo ONISHI, Kiyosu-shi, Aichi (JP); Takeki SATO, Kiyosu-shi, Aichi (JP)

(73) Assignee: FUJIMI INCORPORATED, Kiyosu-shi, Aichi (JP)

(21) Appl. No.: 16/085,312

(22) PCT Filed: Mar. 10, 2017
(86) PCT No.: PCT/JP2017/009802

§ 371 Date: Sep. 14, 2018

(30) Foreign Application Priority Data
Mar. 25, 2016 (JP) 2016-061554

(51) Int. Cl. C09G 1/02; H01L 21/321; H01L 21/768

(52) U.S. Cl. CPC C09G 1/02; H01L 21/7684; H01L 21/3212

(57) ABSTRACT

The present invention provides a polishing composition for an object to be polished having a metal-containing layer, by which sufficient flattening can be achieved. The present invention is a polishing composition used for polishing an object to be polished having a metal-containing layer, the polishing composition including: abrasive grains; an acid; an oxidizer; and a dispersing medium, wherein an acid dissociation constant (pKa) of the acid is higher than a pH of the composition.

### TECHNICAL FIELD

The present invention relates to a polishing composition for an object to be polished having a metal-containing layer.

### BACKGROUND ART

In recent years, with high-level integration resulting from the miniaturization of an LSI production process, electronic devices including computers have been decreased in size and improved in performance such as multiple functions or high speed. In new fine processing technologies along with such high-level integration of LSI, a chemical mechanical polishing (hereinafter, also simply referred to as “CMP”) method is used. The CMP method is technology that is frequently utilized for the flattening of an interlayer insulating film, formation of a metal plug, and formation of embedded wiring (damascene wiring) in the LSI production process, particularly, in a multilayer wiring forming process.

A general method of CMP is a method in which a polishing pad is pasted onto a circular polishing table (platen), the polishing pad surface is immersed with a polishing agent, the surface, on which a metal film is formed, of a substrate is pressed against the polishing pad, the polishing table is rotated in a state in which a predetermined pressure (polishing pressure) is applied from the back surface thereof, and the metal film (for example, tungsten) is removed by the mechanical friction between the polishing agent and the metal film.

Generally, the formation of the metal plug and wiring in the semiconductor device is performed by forming a conductor layer made of a metal as described above on an insulator layer made of silicon oxide in which a recessed part is formed and then removing a part of the conductor layer on the insulator layer by polishing until the insulator layer is exposed. This polishing process is divided broadly into a main polishing step of performing polishing for removing the most part of the conductor layer to be removed and a buff polishing step of performing final polishing to the conductor layer and the insulator layer.

A polishing composition used in the semiconductor device production process generally contains a polishing accelerator such as an acid, an oxidizer, and abrasive grains. In this regard, in JP 2013-42131 A (corresponding to US 2013/045598 A), an oxidizer-free CMP polishing slurry composition has been reported on the basis of the point of view that use of an oxidizer causes recessing of a tungsten plug (a phenomenon that tungsten is excessively polished).

### SUMMARY OF INVENTION

In the composition described in JP 2013-42131 A (corresponding to US 2013/045598 A), the surface after polishing becomes coarse, and thus sufficient flattening cannot be achieved.

Therefore, the present invention has been made in view of the above-described circumstances, and an object thereof is to provide a polishing composition for an object to be polished having a metal-containing layer by which sufficient flattening can be achieved.

Another object of the present invention is to provide a polishing composition for an object to be polished having a metal-containing layer by which a balance between a low etching speed and a high polishing speed can be ensured.

The present inventors have conducted intensive studies in order to solve the above-described problems. As a result, they have found out that by using an acid having a higher acid dissociation constant (pKa) than a pH of the composition, the above-described problems can be solved, thereby completing the present invention.

That is, the above-described objects can be solved by a polishing composition used for polishing an object to be polished having a metal-containing layer, the polishing composition including: abrasive grains; an acid; an oxidizer; and a dispersing medium, wherein an acid dissociation constant (pKa) of the acid is higher than a pH of the composition.

### DESCRIPTION OF EMBODIMENTS

A polishing composition of the present invention is used for polishing an object to be polished having a metal-containing layer. Further, the polishing composition of the present invention contains abrasive grains, an acid, an oxidizer, and a dispersing medium, and at this time, an acid dissociation constant (pKa) of the acid is higher than a pH of the polishing composition. According to the polishing composition having the above-described configuration, the metal-containing layer that is the object to be polished can be smoothly polished. In addition, according to the polishing composition of the present invention, the metal-containing layer that is the object to be polished can be polished at a high polishing speed while an etching speed is suppressed to be low.

Incidentally, in this specification, the “acid dissociation constant (pKa)” is also simply referred to as the “acid dissociation constant” or “pKa.” In addition, the “acid having a higher acid dissociation constant (pKa) than the pH of the polishing composition” is also simply referred to as the “acid according to the present invention.” The “polishing composition for the object to be polished having a metal-containing layer” is also simply referred to as the “polishing composition according to the present invention” or the “polishing composition,”

The composition described in JP 2013-42131 A (corresponding to US 2013/045598 A) contains a diquaternary compound represented by Formula (I) composed of a bivalent cationic site and a bivalent anionic site (particularly, a quaternary amine compound; paragraph [0029]). With existence of this diquaternary compound, the etching speed can be assuredly suppressed to be low. However, the cationic site of this diquaternary compound is adsorbed on the abrasive grain (for example, Si—) surface to induce aggregation of the abrasive grains and further induce precipitation thereof, and thus the stability of the abrasive grains is degraded. Simultaneously, the secondary particle size of the abrasive grains is increased so that the surface after polishing becomes coarse (a value of the surface roughness Ra is increased). Tungsten has been applied from the early stage of the CMP process startup since tungsten has high electrical conductivity and high embeddability. However, it is widely known that since tungsten has high hardness and high brittleness, processing of tungsten is difficult, and final machined surface roughness is inferior to other metals such as copper and aluminum. In addition thereto, the surface roughening of crystalline grains of tungsten becomes an important problem in accordance with the miniaturization (high-level integration) in recent years, and it is demanded to resolve this surface roughening by a chemical mechanical polishing (CMP) method. For this reason, with the composition described in JP 2013-42131 A (corresponding to US 2013/045598 A), flattening that is currently demanded cannot be sufficiently achieved. Further, in the composition described in JP 2013-42131 A (corresponding to US 2013/045598 A), potassium iodate is essentially used as an oxidizer, and this oxidizer promotes formation of a metal oxide film (for example, a tungsten oxide (WO₃) film). However, this potassium iodate causes iodine gas to be generated. The iodine gas induces cough, stridor, feeling of smothering, and the like when a human inhales the iodine gas. For this reason, it is necessary to strictly manage working environment at the time of production of the composition and polishing operation using the composition, for example, it is necessary to carry out sufficient ventilation, or it is necessary for a worker to wear protective gloves and protective clothing. Therefore, in consideration of working environment soundness in recent years, it is desirable that a compound containing iodine possibly cannot be used as possible.

In this regard, the present invention has a feature that an acid having a higher acid dissociation constant (pKa) than a pH of the polishing composition is used. With this configuration, without using the above-described diquaternary compound, a metal-containing layer (an object to be polished having a metal-containing layer) can be polished smoothly (to have a low surface roughness (Ra)). Further, by using the polishing composition of the present invention, the metal-containing layer (the object to be polished having a metal-containing layer) can be polished at a high polishing speed while the etching speed is suppressed to be low. Detailed mechanism exhibiting the above effect is not clear but is considered as follows. Incidentally, the following mechanism is merely speculation and does not limit the technical scope of the present invention. That is, as described above, in the related art, since a metal film including tungsten is difficult to etch, attention has been paid to polishing of a metal-containing layer at a high polishing speed. However, in recent years, since a technology by which a metal-containing layer can be formed in a thin film has been developed, improvement in polishing speed becomes less important. Instead, attention has been paid to the flattening of the surface in accordance with the miniaturization of the LSI production process. In general, the chemical mechanical polishing (CMP) of a metal-containing layer is performed by the mechanism as described below: the surface of the metal-containing layer is oxidized by an oxidizer contained in a polishing composition to form a metal oxide film. The metal-containing layer is polished by the metal oxide film being physically scraped off by abrasive grains, and the polished metal surface is also oxidized by the oxidizer to form a metal oxide film, and this metal oxide film is scraped off by the abrasive grains. This operation cycle is repeated. However, in the method of the related art, there is a problem in that the substrate surface after polishing does not have sufficient smoothness. The present inventors have conducted intensive studies on the above-described problems, and as a result, have speculated that degradation in surface roughness is caused by corrosion of a grain boundary between crystalline grains. That is, it is speculated that, although a metal oxide (for example, tungsten oxide) is in contact with water to form a metal hydroxide (for example, tungsten hydroxide) so that the metal oxide is dissolved, the speed of dissolving by this chemical reaction is higher than the speed of scrapping-off of the abrasive grains and thus the etching speed increases so that the surface roughening occurs. In this regard, increasing of the speed of scrapping-off of the abrasive grains has been reviewed as a solving means, but it is necessary to increase the concentration of the abrasive grains and thus it is considered that practicality is low due to an increase in cost. For this reason, the present inventors have conducted intensive studies on another means for suppressing the above-described dissolving, and as a result, have considered that it is effective to use an acid having low chelating ability, that is, having a higher pKa than a pH of the composition. Specifically, pKa is an index for the amount of a group obtained by dissociation of the acid (for example, a carboxyl group), and a higher pKa means that the dissociating group is less. Therefore, by using an acid having a high pKa, the chelating ability of the acid is decreased so that by using a composition containing such an acid, it is possible to suppress dissolving (eluting) of a metal (for example, tungsten) from a substrate at the time of polishing and to decrease surface roughness after polishing.

Therefore, according to the polishing composition of the present invention, a metal-containing layer (object to be polished) can be polished at a high polishing speed while an etching speed is suppressed to be low. Further, since elution of the metal can be suppressed, when the metal-containing layer (object to be polished) is polished by the polishing composition of the present invention, the surface roughness (Ra) can be decreased, and thus a layer (substrate) having a flat surface can be obtained. In addition, according to the polishing composition of the present invention, without the concentration of the abrasive grains being increased, the metal-containing layer (object to be polished) can be polished to have a smooth surface at a high polishing speed while the etching speed is suppressed to be low.

Hereinafter, embodiments of the present invention will be described. Incidentally, the present invention is not limited to only the following embodiments.

Further, in this specification, unless particularly stated otherwise, operations and measurement of physical properties are carried out under the conditions of room temperature (20 to 25° C.)/relative humidity of 40 to 50% RH.

[Object to Be Polished]

The object to be polished according to the present invention is a metal-containing layer. Herein, the metal-containing layer is not particularly limited long as at least a surface that is a target to be polished contains a metal. For this reason, the metal-containing layer may be a substrate formed by a metal or a substrate having a metal-containing layer or a layer formed by a metal (for example, a substrate in which a metal-containing layer or a layer formed by a metal is disposed on a substrate made of a Polymer or another metal). Preferably, the metal-containing layer is a layer (for example, a substrate) formed by a metal or an object to be polished (for example, a substrate) having a layer formed by a metal.

Herein, the metal is not particularly limited. Examples thereof include tungsten, copper, aluminum, cobalt, hafnium, nickel, gold, silver, platinum, palladium, rhodium, ruthenium, iridium, and osmium. The metal may be contained in the form of an alloy or a metal compound. These metals may be used singly or as a mixture of two or more kinds. The polishing composition of the present invention can be suitably used for the high-level integration technology along with the miniaturization of the LSI production process, and particularly, is suitable when a plug around a transistor or a material for a via hole is polished. In addition, as a material to be filled, tungsten, copper, aluminum, and cobalt are preferable, and tungsten is more preferable. That, is, according to the particularly preferred embodiment of the present invention, the metal is tungsten (the polishing composition of the present invention is used for polishing a layer containing tungsten).

[Polishing Composition]

The polishing composition of the present invention contains abrasive grains, an acid, an oxidizer, and a dispersing medium, and at this time, an acid dissociation constant (pKa) of the acid is higher than a pH of the polishing composition. Hereinafter, the configuration of the polishing composition of the present invention will be described.

(Abrasive Grains)

The polishing composition of the present invention essentially contains abrasive grains. The abrasive grains contained in the polishing composition have an action of mechanically polishing an object to be polished and improve the polishing speed of the object to be polished by the polishing composition.

The abrasive grains to be used may be any of inorganic particles, organic particles, and organic-inorganic composite particles. Specific examples of the inorganic particles include particles composed of a metal oxide such as silica, alumina, ceria, or titania, silicon nitride particles, silicon carbide particles, and boron nitride particles. Specific examples of the organic particles include polymethyl methacrylate (PMMA) particles. The abrasive grains may be used singly or as a mixture of two or more kinds. Moreover, as the abrasive grains, a commercially available product or a synthetic product may be used.

Among these abrasive grains, silica is preferable and colloidal silica is particularly preferable.

The abrasive grains may be surface-modified. The value of the zeta potential of typical colloidal silica is close to zero under an acidic condition, and thus silica particles tend to aggregate without electrically repelling one another under an acidic condition. On the other hand, the abrasive grains which are surface-modified so as to have a relatively large negative zeta potential value even under the acidic condition strongly repel one another even under the acidic condition to be favorably dispersed. As a result, the storage stability of the polishing composition is improved. Such surface-modified abrasive grains can be obtained, for example, by mixing a metal such as aluminum, titanium, or zirconium or an oxide thereof with the abrasive grains and doping on the surface of the abrasive grains.

Among them, colloidal silica having an organic acid immobilized is particularly preferable. The immobilization of an organic acid on the surface of colloidal silica to be contained in the polishing composition is performed, for example, by chemically bonding the functional group of the organic acid on the surface of colloidal silica. The immobilization of the organic acid to colloidal silica cannot be accomplished by only allowing colloidal silica to simply coexist with an organic acid. It is possible to perform the immobilization, for example, by the method described in “Sulfonic acid-functionalized silica through quantitative oxidation of thiol groups,” Chem. Commun. 246-247 (2003) when sulfonic acid of a kind of organic acids is immobilized on colloidal silica. Specifically, it is possible to obtain colloidal silica having sulfonic acid immobilized on the surface by coupling a silane coupling agent having a thiol group such as 3-mercaptopropyl trimethoxysilane to colloidal silica and then oxidizing the thiol group with hydrogen peroxide. Alternatively, it is possible to perform the immobilization, for example, by the method described in “Novel Silane Coupling Agents Containing a Photolabile 2-Nitrobenzyl Ester for Introduction of a Carboxy Group on the Surface of Silica Gel,” Chemistry Letters, 3, 228-229 (2000) when carboxylic acid is immobilized on colloidal silica. Specifically, it is possible to obtain colloidal silica having carboxylic acid immobilized on the surface by coupling a silane coupling agent containing a photoreactive 2-nitrobenzyl ester to colloidal silica and then irradiating with light.

Further, the average association degree of the abrasive grains is preferably less than 5.0, more preferably 3.0 or less, and further preferably 2.5 or less. As the average association degree of the abrasive grains is decreased, when the average association degree is within such a range, the surface roughness caused by the shape of the abrasive grains can be made favorable. In addition, the average association degree of the abrasive grains is preferably 1.0 or more and more preferably 1.05 or more. The average association degree is obtained by dividing the value of the average secondary particle size of the abrasive grains by the value of the average primary particle size. As the average association degree of the abrasive grains is increased, there is an advantageous effect that the polishing speed of the object to be polished is improved by the polishing composition.

The lower limit of the average primary particle size of the abrasive grains is preferably 10 nm or more, more preferably 15 nm or more, and further preferably 20 nm or more. In addition, the upper limit of the average primary particle size of the abrasive grains is preferably 200 nm or less, more preferably 150 nm or less, and further preferably 100 nm or less. With such a range, the polishing speed of the object to be polished by the polishing composition is improved, and it is possible to further suppress the occurrence of the surface defect on the surface of the object to be polished after being polished using the polishing composition. Incidentally, the average primary particle size of the abrasive grains is calculated, for example, on the basis of the specific surface area of the abrasive grains measured by a BET method.

The lower limit of the average secondary particle size of the abrasive grains is preferably 15 nm or more, more preferably 20 nm or more, and further preferably 30 nm or more. In addition, the upper limit of the average secondary particle size of the abrasive grains is preferably 300 nm or less, more preferably 260 nm or less, and further preferably 220 nm or less. With such a range, the polishing speed of the object to be polished by the polishing composition is improved and also it is possible to further suppress the occurrence of the surface defect on the surface of the object to be polished after being polished using the polishing composition. Incidentally, the secondary particles described herein refer to the particles formed by the association of the abrasive grains in the polishing composition, and the average secondary particle size of these secondary particles can be measured, for example, by a dynamic light scattering method.

The upper limit of the aspect ratio of the abrasive grains in the polishing composition is preferably less than 2.0, more preferably 1.8 or less, and further preferably 1.5 or less. With such a range, the surface roughness caused by the shape of the abrasive grains can be made favorable. Incidentally, the aspect ratio is an average of a value obtained by dividing the length of the long side of the smallest rectangle circumscribing the image of the abrasive grain particles taken by a scanning electron microscope by the length of the short side of the same rectangle and can be obtained using general image analysis software. The lower limit of the aspect ratio of the abrasive grains in the polishing composition is 1.0 or more. As the aspect ratio is closer to this value, the surface roughness caused by the shape of the abrasive grains can be made favorable.

The lower limit of the ratio D90/D10 of the diameter (D90) of particles when the cumulative particle weight from the fine particle side reaches 90% of the total particle weight to the diameter (D10) of particles when the cumulative particle weight from the fine particle side reaches 10% of the total particle weight of the entire particles is preferably 1.1 or more, more preferably 1.2 or more, and further preferably 1.3 or more in the particle size distribution of the abrasive grains in the polishing composition determined by a laser diffraction scattering method. In addition, the upper limit of the ratio D90/D10 of the diameter (D90) of particles when the cumulative particle weight from the fine particle side reaches 90% of the total particle weight to the diameter (D10) of particles when the cumulative particle weight from the fine particle side reaches 10% of the total particle weight of the entire particles is not particularly limited, and is preferably 2.04 or less in the particle size distribution of the abrasive grains in the polishing composition determined by a laser diffraction scattering method. With such a range, the surface roughness caused by the shape of the abrasive grains can be made favorable.

The lower limit of the content of the abrasive grains in the polishing composition is preferably 0.1% by mass or more, more preferably 0.5% by mass or more, and further preferably 1% by mass or more. In addition, the upper limit of the content of the abrasive grains in the polishing composition is preferably 50% by mass or less, more preferably 30% by mass or less, and further preferably 20% by mass or less. With such a range, the polishing speed of the object to be polished is improved, it is possible to suppress the cost of the polishing composition, and it is possible to further suppress the occurrence of the surface defect on the surface of the object to be polished after being polished using the polishing composition.

(Acid)

The polishing composition of the present invention essentially contains an acid having a higher acid dissociation constant (pKa) than a pH of the composition. The acid according to the present invention acts as an anticorrosive. For this reason, with the existence of the acid according to the present invention, it is possible to suppress the dissolving (eluting) of the metal that is a target to be polished and to polish the metal-containing layer (object to be polished) smoothly (at a low surface roughness (Ra)). Further, it is possible to polish the metal-containing layer (object to be polished) at a high polishing speed while the etching speed is suppressed to be low.

In this specification, the acid dissociation constant (pKa) of the acid is an index of acidity, and a common logarithm is employed as a reciprocal of the dissociation constant (Ka) of acid. That is, the acid dissociation constant (pKa) of the acid is obtained by measuring the dissociation constant Ka=[H₃O⁺] [B⁻]/[BH] under a dilute aqueous solution condition and using a formula: pKa=−log Ka Incidentally, in the above formula, BH represents an organic acid and B⁻ represents a conjugate base of an organic acid. The measurement method of pKa is as follows: a hydrogen ion concentration is measured using a pH meter and pKa can be calculated from the concentration of the substance and the hydrogen ion concentration. Incidentally, in the case of polybasic acid, the pKa is a value calculated for the first Ka (pKa1).

Herein, a difference between the pH of the polishing composition and the acid dissociation constant of the acid is not particularly limited as long as it satisfies a relation: the pH of the polishing composition<the pKa of the acid. In consideration of further improvement in the effect of suppressing the dissolving (eluting) of the metal, the difference between the acid dissociation constant (pKa) of the acid and the pH of the composition [=(the acid dissociation constant (pKa) of the acid)−(the pH of the composition)] is preferably 0.9 or more, more preferably 1.0 or more, and further preferably 1.2 or more, particularly preferably more than 1.4. The acid satisfying such a difference more effectively suppresses the dissolving (eluting) of the metal from the substrate and thus the surface roughness of the metal-containing layer (object to be polished) after being polished can be further decreased. Further, in the case of using the polishing composition containing such an acid, the etching speed at the time of polishing can be further decreased while the polishing speed is maintained to be high.

Herein, the pKa of the acid is not particularly limited as long as it is higher than the pH of the polishing composition, and can be appropriately selected according to the type of metal that is a target to be polished. Specifically, the acid dissociation constant (pKa) of the acid is preferably 2.9 or more and less than 5.0, more preferably more than 3.0 and 4.9 or less, further preferably 3.2 or more and 4.8 or less, and particularly preferably more than 3.4 and 4.8 or less. The acid having such a pKa more effectively suppresses the dissolving (eluting) of the metal from the substrate and thus the surface roughness of the metal-containing layer (object to be polished) after being polished can be further decreased. Further, in the case of using the polishing composition containing such an acid, the etching speed at the time of polishing can be further decreased while the polishing speed is maintained to be high.

Any acid may be used as the acid as long as it has a higher pKa than the pH of the polishing composition, and from the viewpoint of performance of suppressing the dissolving of the metal, the acid is preferably an organic acid having a carboxyl group and an organic acid having a carboxyl group and a hydroxyl group at the terminal (that is, —CH₂OH). Specific examples thereof include citric acid, succinic acid, malonic acid, tartaric acid, lactic acid, malic acid, acetic acid, phthalic acid, glycolic acid, crotonic acid, valeric acid, 2-hydroxybutyric acid, γ-hydroxybutyric acid, 2-hydroxyisobutyric acid, 3-hydroxyisobutyric acid, glyceric acid, benzoic acid, leucine acid, propionic acid, butyric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, salicylic acid, oxalic acid, glutaric acid, adipic acid, pimelic acid, malic acid, and mandelic acid. Among these, succinic acid, acetic acid, phthalic acid, glycolic acid, crotonic acid, valeric acid, γ-hydroxybutyric acid, 2-hydroxyisobutyric acid, 3-hydroxyisobutyric acid, and benzoic acid are preferable. Such an acid more effectively suppresses the dissolving (eluting) of the metal from the substrate and thus the surface roughness of the metal-containing layer (object to be polished) after being polished can be further decreased. Further, in the case of using the polishing composition containing such an acid, the etching speed at the time of polishing can be further decreased while the polishing speed is maintained to be high.

The acid may be used singly or may be used in the form of a mixture of two or more kinds. Incidentally, the acid dissociation constant (pKa) of the acid in the case of using two of more kinds of acid can be measured by the above-described method.

The content of the acid in the polishing composition is not particularly limited, and is preferably such an amount that the pH of the polishing composition is 1 or more and 7 or less and more preferably such an amount that the pH of the polishing composition is 1.05 or more and 5 or less. Such a pH of the polishing composition is excellent in terms of storage stability. In addition, it is easy to handle the polishing composition. Moreover, the polishing speed of the metal that is the object to be polished can be improved.

(Oxidizer)

The polishing composition of the present invention essentially contains an oxidizer in addition to the abrasive grains and the acid. The oxidizer according to the present invention is not particularly limited, and a peroxide is preferable. That is, according to the preferred embodiment of the present invention, the oxidizer is a peroxide. Specific examples of such peroxide include, although not limited to the following, hydrogen peroxide, peracetic acid, a percarbonate salt, urea peroxide, sodium persulfate, potassium persulfate, ammonium persulfate, potassium monopersulfate, and oxone. The oxidizer may be used singly or as a mixture of two or more kinds. That is, according to the preferred embodiment of the present invention, the peroxide is at least one kind selected from the group consisting of hydrogen peroxide, peracetic a percarbonate salt, urea peroxide, sodium persulfate, potassium persulfate, ammonium persulfate, potassium monopersulfate, and oxone. As the oxidizer, a persulfate salt (sodium persulfate, potassium persulfate, or ammonium persulfate) and hydrogen peroxide are more preferable and hydrogen peroxide is particularly preferable.

The lower limit of the content (concentration) of the oxidizer in the polishing composition is preferably 0.001% by mass or more, more preferably 0.005% by mass or more, and further preferably 0.01% by mass or more. There is an advantage that it is possible to improve the polishing speed by the polishing composition is improved as the content of the oxidizer increases. In addition, the upper limit of the content (concentration) of the oxidizer in the polishing composition is preferably 10% by mass or less, more preferably 5% by mass or less, and further preferably 1% by mass or less. There are advantages that it is possible to suppress the material cost of the polishing composition and it is possible to diminish the burden to treat the polishing composition after using for polishing, that is, the load of the waste water treatment as the content of the oxidizer decreases. In addition, there is also an advantage that the excessive oxidation of the surface of the object to be polished is less likely to occur and thus roughness of the metal surface after polishing is decreased.

Incidentally, since an oxide film is formed on the surface of the metal-containing layer by the oxidizer, the oxidizer is preferably added immediately before polishing.

(Dispersing Medium)

The polishing composition of the present invention contains a dispersing medium for dispersing or dissolving each component. Herein, the dispersing medium is not particularly limited, and water is preferable. From the viewpoint of suppressing the inhibition of the impurities on the action of other components, water containing impurities as little as possible is preferable, and specifically, pure water, ultrapure water, or distilled water from which the impurity ions are removed by an ion exchange resin and the foreign matters are removed through a filter is preferable.

(Other Components)

As described above, the polishing composition of the present invention essentially contains the abrasive grains, the acid, the oxidizer, and the dispersing medium, but may contain other additives in addition to the above-described components. Herein, other additives are not particularly limited, and additives to be generally added to the polishing composition can be used. Specific examples thereof include a complexing agent, a metal anticorrosive, an antiseptic agent, an antifungal agent, a reductant, a water-soluble polymer, and an organic solvent for dissolving a sparingly soluble organic substance. Incidentally, the polishing composition of the present invention does not substantially contain, for example, a diquaternary compound described in JP 2013-42131 A. Further, the polishing composition of the present invention does not substantially contain an iodine compound (for example, potassium iodate) that may be a trigger of iodine gas occurrence. Herein, the expression “does not substantially contain” means that a target substance exists in a ratio of 10% by mass or less (lower limit: 0% by mass) with respect to the polishing composition, and exists preferably in a ratio of 5% by mass or less (lower limit: 0% by mass).

Hereinafter, among the above-described other additives, a complexing agent, a metal anticorrosive, an antiseptic agent, and an antifungal agent will be described.

A complexing agent that may be contained in the polishing composition as necessary has an action of chemically etching the surface of the object to be polished and can more effectively improve the polishing speed of the object to be polished by the polishing composition.

Examples of the usable complexing agent include an inorganic acid or a salt thereof, an organic acid or a salt thereof, a nitrile compound, an amino acid, and a chelating agent. These complexing agents may be used singly or as a mixture of two or more kinds. In addition, as the complexing agent, a commercially available product or a synthetic product may be used.

As the complexing agent, a salt of the inorganic acids or organic acids may be used. It is possible to expect the pH buffering action particularly in the case of using a salt produced by a weak acid and a strong base, a salt produced by a strong acid and a weak base, or a salt produced by a weak acid and a weak base. Examples of such a salt include potassium chloride, sodium sulfate, potassium nitrate, potassium carbonate, potassium tetrafluoroborate, potassium pyrophosphate, potassium oxalate, trisodium citrate, (+)-potassium tartrate, and potassium hexafluorophosphate.

Specific examples of the nitrile compound include acetonitrile, aminoacetonitrile, propionitrile, butyronitrile, isobutyronitrile, benzonitrile, glutarodinitrile, and methoxyacetonitrile.

Specific examples of the amino acid include glycine, α-alanine, β-alanine, N-methyl glycine, N,N-dimethyl glycine, 2-aminobutyric acid, norvaline, valine, leucine, norleucine, isoleucine, phenylalanine, proline, sarcosine, ornithine, lysine, taurine, serine, threonine, homoserine, tyrosine, bicine, tricine, 3,5-diiodo-tyrosine, β-(3,4-dihydroxyphenyl)-alanine, thyroxine, 4-hydroxy-proline, cysteine, methionine, ethionine, lanthionine, cystathionine, cystine, cysteic acid, aspartic acid, glutamic acid, S-(carboxymethyl)-cysteine, 4-aminobutyric acid, asparagine, glutamine, azaserine, arginine, canavanine, citrulline, δ-hydroxy-lysine, creatine, histidine, 1-methyl-histidine, 3-methyl-histidine, and tryptophan.

Specific examples of the chelating agent include nitrilotriacetlc acid, diethylenetriaminepentaacetic acid, ethylenediaminetetraacetic acid, N,N,N-trimethylenephosphonic acid, ethylenediamine-N,N,N′,N′-tetramethylenesulfonic acid, transcyclohexanediaminetetraacetic acid, 1,2-diaminopropanetetraacetic acid, glycol ether diamine tetraacetic acid, ethylenediamineortho-hydroxyphenylacetic acid, ethylenediaminesuccinic acid (SS isomer), N-(2-carboxylate ethyl)-L-aspartic acid, β-alaninediacetic acid, 2-phosphonobutane-1,2,4-tricarboxylic acid, 1-hydroxyethylidene-1,1-diphosphonic acid, N,N′-bis(2-hydroxybenzyl)ethylenediamine-N,N′-diacetic acid, and 1,2-dihydroxybenzene-4,6-disulfonic acid.

Among these, at least one kind selected from the group consisting of an inorganic acid or a salt thereof, a carboxylic acid or a salt thereof, and a nitrile compound is preferable, and from the viewpoint of the stability of the complex structure with the metal compound contained in the object to be polished, an inorganic acid or a salt thereof is more preferable.

The content (concentration) of the complexing agent in a case where the polishing composition contains the complexing agent is not particularly limited. For example, the lower limit of the content (concentration) of the complexing agent is not particularly limited since the effect is exhibited even in a small amount, and is preferably 0.001 g/L or more, more preferably 0.01 g/L or more, and further preferably 1 g/L or more. In addition, the upper limit of the content (concentration) of the complexing agent is preferably 20 g/L or less, more preferably 15 g/L or less, and further preferably 10 g/L or less. With such a range, this is advantageous in terms of improving the polishing speed of the object to be polished and improving the flatness of the surface of the object to be polished after being polished using the polishing composition.

Next, the metal anticorrosive that may be contained in the polishing composition as necessary acts such that dissolving of the metal is prevented so as to suppress deterioration of surface state such as the surface roughening of the polished surface. However, since the acid according to the present invention acts as the metal anticorrosive, the polishing composition of the present invention can sufficiently suppress or prevent dissolving of the metal without the metal anticorrosive being separately added.

The usable metal anticorrosive is not particularly limited, and is preferably a heterocyclic compound or a surfactant. The number of members constituting the heterocyclic ring in the heterocyclic compound is not particularly limited. In addition, the heterocyclic compound may be a single ring compound or a polycyclic compound having a condensed ring. The metal anticorrosive may be used singly or as a mixture of two or more kinds. Moreover, as the metal anticorrosive, a commercially available product or a synthetic product may be used.

Specific examples of the heterocyclic compound usable as the metal anticorrosive include nitrogen-containing heterocyclic compounds such as a pyrrole compound, a pyrazole compound, an imidazole compound, a triazole compound, a tetrazole compound, a pyridine compound, a pyrazine compound, a pyridazine compound, a pyrindine compound, an indolizine compound, an indole compound, an isoindole compound, an indazole compound, a purine compound, a quinolizine compound, a quinoline compound, an isoquinoline compound, a naphtyridine compound, a phthalazine compound, a quinoxaline compound, a quinazoline compound, a cinnoline compound, a buterizine compound, a thiazole compound, an isothiazole compound, an oxazole compound, an isoxazole compound, and a furazan compound.

For more specific examples, examples of the pyrazole compound include 1H-pyrazole, 4-nitro-3-pyrazole carboxylic acid, 3,5-pyrazole carboxylic acid, 3-amino-5-phenyl pyrazole, 5-amino-3-phenyl pyrazole, 3,4,5-tribromopyrazole, 3-aminopyrazole, 3,5-dimethylpyrazole, 3,5-dimethyl-1-hydroxymethyl pyrazole, 3-methylpyrazole, 1-methylpyrazole, 3-amino-5-methylpyrazole, 4-amino-pyrazolo[3,4-d]pyrimidine, allopurinol, 4-chloro-1H-pyrazolo[3,4-D]pyrimidine, 3,4-dihydroxy-6-methylpyrazolo(3,4-B)-pyridine, and 6-methyl-1H-pyrazolo[3,4-b]pyridine-3-amine.

Examples of the imidazole compound include imidazole, 1-methylimidazole, 2-methylitnidazole, 4-methylimidazole, 1,2-dimethylpyrazole, 2-ethyl-4-methylimidazole, 2-isopropylimidazole, benzimidazole, 5,6-dimethylbenzimidazole, 2-aminobenzimidazole, 2-chlorobenzimidazole, 2-methylbenzimidazole, 2-(1-hydroxyethyl)benzimidazole, 2-hydroxybenzimidazole, 2-phenylbenzimidazole, 2,5-dimethylbenzimidazole, 5-methylbenzimidazole, and 5-nitrobenzimidazole.

Examples of the triazole compound include 1,2,3-triazole(1H-BTA), 1,2,4-triazole, 1-methyl-1,2,4-triazole, methyl-1H-1,2,4-triazole-3-carboxylate, 1,2,4-triazole-3-carboxylic acid, methyl 1,2,4-triazole-3-carboxylate, 1H-1,2,4-triazole-3-thiol, 3,5-diamino-1H-1,2,4-triazole, 3-amino-1,2,4-triazole-5-thiol, 3-amino 1H-1,2,4-triazole, 3-amino-5-benzyl-4H-1,2,4-triazole, 3-amino-5-methyl-4H-1,2,4-triazole, 3-nitro-1,2,4-triazole, 3-bromo-5-nitro-1,2,4-triazole, 4-(1,2,4-triazole-1-yl)phenol, 4-amino-1,2,4-triazole, 4-amino-3,5-dipropyl-4H-1,2,4-triazole, 4-amino-3,5-dimethyl-4H-1,2,4-triazole, 4-amino-3,5-dipeptyl-4H-1,2,4-triazole, 5-methyl-1,2,4-triazole-3,4-diamine, 1H-benzotriazole, 1-hydroxybenzotriazole, 1-aminobenzotriazole, 1-carboxybenzotriazole, 5-chloro-1H-benzotriazole, 5-nitro-1H-benzotriazole, 5-carboxy-1H-benzotriazole, 5-methyl-1H-benzotriazole, 5,6-dimethyl-1H-benzotriazole, 1-(1′,2′-dicarboxyethyl)benzotriazole, 1-[N,N-bis(hydroxyethyl)aminomethyl]benzotriazole, 1-[N,N-bis(hydroxyethyl)aminomethyl]-5-methylbenzotriazole, and 1-[N,N-bis(hydroxyethyl)aminomethyl]-4-methylbenzotriazole.

Examples of the tetrazole compound include 1H-tetrazole, 5-methyltetrazole, 5-aminotetrazole, and 5-phenyltetrazole.

Examples of the indazole compound include 1H-indazole, 5-amino-1H-indazole, 5-nitro-1H-indazole, 5-hydroxy-1H-indazole, 6-amino-1H-indazole, 6-nitro-1H-indazole, 6-hydroxy-1H-indazole, and 3-carboxy-5-methyl-1H-indazole.

Examples of the indole compound include 1H-indole, 1-methyl-1H-indole, 2-methyl-1H-indole, 3-methyl-1H-indole, 4-methyl-1H-indole, 5-methyl-1H-indole, 6-methyl-1H-indole, 7-methyl-1H-indole, 4-amino-1H-indole, 5-amino-1H-indole, 6-amino-1H-indole, 7-amino-1H-indole, 4-hydroxy-1H-indole, 5-hydroxy-1H-indole, 6-hydroxy-1H-indole, 7-hydroxy-1H-indole, 4-methoxy-1H-indole, 5-methoxy-1H-indole, 6-methoxy-1H-indole, 7-methoxy-1H-indole, 4-chloro-1H-indole, 5-chloro-1H-indole, 6-chloro-1H-indole, 7-chloro-1H-indole, 4-carboxy-1H-indole, 5-carboxy-1H-indole, 6-carboxy-1H-indole, 7-carboxy-1H-indole, 4-nitro-1H-indole, 5-nitro-1H-indole, 6-nitro-1H-indole, 7-nitro-1H-indole, 4-nitrile-1H-indole, 5-nitrile-1H-indole, 6-nitrile-1H-indole, 7-nitrile-1H-indole, 2,5-dimethyl-1H-indole, 1,2-dimethyl-1H-indole, 1,3-dimethyl-1H-indole, 2,3-dimethyl-1H-indole, 5-amino-2,3-dimethyl-1H-indole, 7-ethyl-1H-indole, 5-(aminomethyl)indole, 2-methyl-5-amino-1H-indole, 3-hydroxymethyl-1H-indole, 6-isopropyl-1H-indole, and 5-chloro-2-methyl-1H-indole.

Among these, a preferred heterocyclic compound is a triazole compound, and particularly, 1H-benzotriazole, 5-methyl-1H-benzotriazole, 5,6-dimethyl-1H-benzotriazole, 1-[N,N-bis(hydroxyethyl)aminomethyl]-5-methylbenzotriazole, 1-[N,N-bis(hydroxyethyl)aminomethyl]-4-methylbenzotriazole, 1,2,3-triazole, and 1,2,4-triazole are preferable. These heterocyclic compounds exhibit a high chemical or physical adsorption force to the surface of the object to be polished and thus can form a stronger protective film on the surface of the object to be polished. This is advantageous in terms of improving the flatness of the surface of the object to be polished after being polished using the polishing composition of the present invention.

In addition, examples of the surfactant used as the metal anticorrosive include an anionic surfactant, a cationic surfactant, and an amphoteric surfactant.

Examples of the anionic surfactant include polyoxyethylene alkyl ether acetic acid, polyoxyethylene alkyl sulfate ester, alkyl sulfate ester, polyoxyethylene alkyl ether sulfonic acid, alkyl ether sulfonic acid, alkyl benzene sulfonic acid, alkyl phosphate ester, polyoxyethylene alkyl phosphate ester, polyoxyethylene sulfosuccinic acid, alkyl sulfosuccinic acid, alkyl naphthalene sulfonic acid, alkyl diphenyl ether disulfonic acid, a salt thereof.

Examples of the cationic surfactant include an alkyl trimethyl ammonium salt, an alkyl dimethyl ammonium salt, an alkyl benzyl dimethyl ammonium salt, and an alkyl amine salt.

Examples of the amphoteric surfactant include alkyl betaine and alkyl amine oxide.

Examples of the nonionic surfactant include polyoxyalkylene alkyl ether such as polyoxyethylene alkyl ether, sorbitan fatty acid ester, glycerin fatty acid ester, polyoxyethylene fatty acid ester, polyoxyethylene alkyl amine, and alkyl alkanolamide. Among them, polyoxyalkylene alkyl ether is preferable.

Among these, a preferred surfactant includes polyoxyethylene alkyl ether acetic acid, polyoxyethylene alkyl ether sulfonic acid salt, alkyl ether sulfonic acid salt, and alkyl benzene sulfonic acid salt. These surfactants exhibit a high chemical or physical adsorption force to the surface of the object to be polished and thus can form a stronger protective film on the surface of the object to be polished. This is advantageous in terms of improving the flatness of the surface of the object to be polished after being polished using the polishing composition of the present invention.

The content (concentration) of the metal anticorrosive in a case where the polishing composition contains the metal anticorrosive is not particularly limited. For example, the lower limit of the content (concentration) of the metal anticorrosive is preferably 0.001 g/L or more, more preferably 0.005 g/L or more, and further preferably 0.01 g/L or more. In addition, the upper limit of the content (concentration) of the metal anticorrosive is preferably 10 g/L or less, more preferably 5 g/L or less, and further preferably 2 g/L or less. With such a range, it is possible to prevent dissolving of the metal and to suppress deterioration of surface state such as the surface roughening of the polished surface.

Further, examples of the antiseptic agent and the antifungal agent that may be contained in the polishing composition as necessary include an isothiazoline-based antiseptic agent such as 2-methyl-4-isothiazoline-3-one or 5-chloro-2-methyl-4-isothiazoline-3-one, paraoxybenzoate esters, and phenoxyethanol. These antiseptic agents and antifungal agents may be used singly or as a mixture of two or more kinds.

[Method for Producing Polishing Composition]

The method for producing a polishing composition of the present invention is not particularly limited, and for example, the polishing composition can be obtained by stirring and mixing abrasive grains, an acid, an oxidizer, and as necessary, other additives in a dispersing medium (for example, water). That is, the present invention also provides a method for producing a polishing composition, the method including mixing the abrasive grains, the acid, and the oxidizer.

Incidentally, as described above, since the oxidizer promotes the formation of an oxide film on the surface of the metal-containing layer, it is preferable that the abrasive grains, the acid, and as necessary, other additives are first added to the dispersing medium (for example, water) to prepare a precursor composition, and the oxidizer is added to the precursor composition immediately before polishing.

A temperature when respective components are mixed is not particularly limited, and is preferably 10 to 40° C., and heating may be carried out in order to increase a rate of dissolution. In addition, a mixing time is also not particularly limited as long as uniform mixing can be carried out.

[Polishing Method and Method for Producing Substrate]

As described above, the polishing composition of the present invention is suitably used for polishing a metal-containing layer (object to be polished). Therefore, the present invention also provides a polishing method of polishing an object to be polished having a metal-containing layer by the polishing composition of the present invention. In addition, the present invention provides a method for producing a substrate, the method including a process of polishing an object to be polished having a metal-containing layer by the polishing method.

As the polishing apparatus, it is possible to use a general polishing apparatus which is equipped with a holder to hold a substrate having an object to be polished and the like, a motor capable of changing the rotation speed and the like and has a polishing table capable of being attached with a polishing pad (polishing cloth).

As the polishing pad, it is possible to use general nonwoven fabric, polyurethane, a porous fluorine resin, and the like without particular limitation. The polishing pad is preferably subjected to a grooving process so as to store polishing liquid.

Regarding the polishing condition, for example, the rotation speed of the polishing table is preferably 10 to 500 rpm. The pressure applied to the substrate having an object to be polished (polishing pressure) is preferably 0.5 to 10 psi. The method of supplying the polishing composition to the polishing pad is not also particularly limited, and for example, a method of continuously supplying the polishing composition by a pump or the like is employed. There is no limitation on the supply amount, and it is preferable that the surface of the polishing pad is covered with the polishing composition of the present invention at all times.

After the polishing is completed, the substrate is washed with running water and the water droplets attached on the substrate are shaken off and dried by a spin dryer or the like, thereby obtaining a substrate having a metal-containing layer.

The polishing composition of the present invention may be a one-component type or a multi-component type including a two-component type. As described above, the oxidizer promotes the formation of the oxide film on the surface of the metal-containing layer. For this reason, the polishing composition is preferably a two-component type composed of a first liquid containing abrasive grains, and an acid, a dispersing medium (for example, water), and as necessary, other additives and a second liquid containing an oxidizer and as necessary, a dispersing medium (for example, water). In addition, the polishing composition of the present invention may be prepared by diluting a stock solution of the polishing composition, for example, 10 times or more using a diluent such as water.

The polishing composition of the present invention is preferably used in a metal polishing process, particularly, in a tungsten polishing process. Further, when the tungsten polishing process is divided broadly into a main polishing step, which is performed for removing the most part of a layer containing tungsten, and a buff polishing step in which the layer containing tungsten and an insulator layer are subjected to final polishing, the polishing composition of the present invention is preferably used in the buff polishing step.

### EXAMPLES

The present invention will be described in more detail using the following Examples and Comparative Examples. However, the technical scope of the present invention is not limited to only the following Examples. Incidentally, unless particularly stated otherwise, “%” and “part(s)” mean “% by mass” and “part(s) by mass,” respectively. Further, in the following Examples, unless particularly stated otherwise, the operations were carried out under the conditions of room temperature (25° C.)/relative humidity of 40 to 50% RH.

### Examples 1 to 15 and Comparative Example 1

A polishing composition was prepared by adding abrasive grains (sulfonic acid-immobilized colloidal silica; average primary particle size: 30 nm, average secondary particle size: 60 nm, aspect ratio: 1.24, D90/D10: 2.01) to 1 L of pure water to have an amount of 2.0% by mass with respect to the final polishing composition, and then adding an acid presented in the following Table 1 thereto. Incidentally, the acid was added such that the pH of the polishing composition before addition of an oxidizer to be described later became 2.0. Further, a hydrogen peroxide solution (30% by mass) was added as the oxidizer to the polishing composition under stirring immediately before polishing a tungsten wafer to have an amount of 0.45% by mass with respect to the final polishing composition. The pH of the final polishing composition after addition of the oxidizer is collectively presented in Table 1. The pH of the polishing composition (liquid temperature: 25° C.) was confirmed by a pH meter (manufactured by HORIBA, Ltd., model number: LAQUA).

### Example 16

A polishing composition was prepared in the same manner as in Example 12, except that the abrasive grains were changed to unmodified colloidal silica (average primary particle size: 30 nm, average secondary particle size: 60 nm, aspect, ratio: 1.24, D90/D10: 2.01).

Regarding the polishing composition thus obtained, the polishing speed (removal rate) (Å/min), the etching speed (etching rate) (Å/min), and the surface roughness were evaluated according to the following methods. The results thereof are presented in the following Table 1.

[Measurement of Polishing Speed (Removal Rate)]

An object to be polished is polished using each polishing composition under the following polishing conditions. The thickness (film thickness) of the object to be polished before and after the polishing is measured by a manual sheet resistor (VR-120, manufactured by Hitachi Kokusai Electric Inc.). The polishing speed (removal rate) (Å/min) is obtained by dividing a difference in thickness (film thickness) of the object to be polished before and after the polishing by the polishing time on the basis of the following (Calculation Method of Polishing Speed). Incidentally, a tungsten wafer (size: 32 mm×32 mm) is used as the object to be polished.

[Chem. 1]

(Polishing Conditions)

Polishing machine: CMP single-sided polishing machine (ENGIS)

Polishing pad: Pad made of polyurethane (IC1010: manufactured by Rohm and Haas Company)

Pressure: 2.0 psi

Rotation speed of platen (table): 70 rpm

Rotation speed of head (carrier): 70 rpm

Flow rate of polishing composition: 150 ml/min

Polishing time: 60 sec

(Calculation Method of Polishing Speed)

The polishing speed (polishing rate) (Å/min) is calculated by the following Formula (1).

$$[ Math . 1 ]$$

$$Polishing speed ( Å \text{/} min ) = \frac{\begin{matrix}[ Film thickness ( Å ) of object \\ to be polished before polishing ] - \\ [ Film thickness ( Å ) of object \\ to be polished after polishing ]\end{matrix}}{[ Polishing time ( min ) ]} \qquad Formula ( 1 )$$

[Measurement of Etching Speed (Etching Rate)]

An etching test is carried out by the following operation. That is, the etching test is carried out by immersing an object to be polished for 10 minutes in a sample container in which 300 mL of each polishing composition is stirred at 300 rpm. The immersed wafer is washed for 30 seconds with pure water and dried by air blow drying using an air gun. The thickness (film thickness) of the object to be polished before and after the etching test is measured by a manual sheet resistor (VR-120, manufactured by Hitachi Kokusai Electric Inc.). The etching speed (etching rate) (Å/min) is obtained by dividing a difference in thickness (film thickness) of the object to be polished before and after the etching test by the etching test time on the basis of the following (Calculation Method of Etching Speed). Incidentally, a tungsten wafer (size: 32 mm×32 mm) is used as the object to be polished.

(Calculation Method of Etching Speed)

The etching speed (etching rate) (Å/min) is calculated by the following Formula (2).

$$[ Math . 2 ]$$

$$Etching speed ( Å \text{/} min ) = \frac{\begin{matrix}[ Film thickness ( Å ) of object \\ to be polished before etching ] - \\ [ Film thickness ( Å ) of object \\ to be polished after etching ]\end{matrix}}{[ Etching time ( min ) ]} \qquad Formula ( 2 )$$

[Measurement of Surface Roughness]

Similarly to the above [Measurement of Polishing Speed (Removal Rate)], an object to be polished is polished using the polishing composition. The surface roughness (Ra) of the polished surface of the object to be polished after the polishing is measured using a scanning probe microscope (SPM). Incidentally, as the SPM, NANO-NAVI 2 manufactured by Hitachi High-Technologies Corporation is used. As a cantilever, SI-DP40P2 is used. Measurement is carried out three times at a scanning frequency of 0.96 Hz, X: 512 pt, and Y: 512 pt, and an average value thereof is regarded as the surface roughness (Ra).

TABLE 1

| | | | pH of | | | |
|---|---|---|---|---|---|---|
| | | | polishing | Etch- | Polish- | Surface |
| | | | composi- | ing | ing | rough- |
| | | | tion after | speed | speed | ness |
| | | | addition | [Å/ | [Å/ | (Ra) |
| | Acid type | pKa | of oxidizer | min] | min] | [nm] |
| Example 1 | Citric acid | 3.09 | 2.11 | 4.2 | 219 | 0.62 |
| Example 2 | Succinic acid | 4.2 | 2.13 | 4.8 | 203 | 0.52 |
| Example 3 | Malonic acid | 2.83 | 2.11 | 11.0 | 220 | 0.76 |
| Example 4 | Tartaric acid | 3.22 | 2.13 | 4.3 | 220 | 0.69 |
| Example 5 | Lactic acid | 3.86 | 2.11 | 7.0 | 207 | 0.79 |
| Example 6 | Malic acid | 3.4 | 2.11 | 6.0 | 207 | 0.81 |
| Example 7 | Acetic acid | 4.76 | 2.11 | 3.8 | 190 | 0.47 |
| Example 8 | Phthalic acid | 2.98 | 2.10 | 4.7 | 211 | 0.82 |
| Example 9 | Glycolic acid | 3.7 | 2.13 | 3.0 | 216 | 0.56 |
| Example 10 | Crotonic | 4.8 | 2.10 | 3.8 | 198 | 0.58 |
| | acid | | | | | |
| Example 11 | Valeric acid | 4.6 | 2.10 | 3.1 | 199 | 0.54 |
| Example 12 | 2-Hydroxy- | 4.37 | 2.10 | 6.0 | 208 | 0.43 |
| | isobutyric | | | | | |
| | acid | | | | | |
| Example 13 | Glyceric acid | 3.4 | 2.11 | 3.9 | 199 | 0.67 |
| Example 14 | Benzoic acid | 4.2 | 2.14 | 3.8 | 192 | 0.48 |
| Example 15 | Leucine acid | 3.9 | 2.14 | 3.3 | 199 | 0.71 |
| Example 16 | 2-Hydroxy- | 4.37 | 2.14 | 3.3 | 180 | 0.85 |
| | isobutyric | | | | | |
| | acid | | | | | |
| Comparative | Maleic acid | 1.9 | 2.11 | 18.0 | 228 | 0.86 |
| Example 1 | | | | | | |

From the results of Table 1 described above, it is found out that by using the polishing composition containing an acid having a higher acid dissociation constant (pKa) than the pH of the composition, a metal (tungsten) substrate can be polished at a nigh polishing speed although the etching speed is low. Further, it is shown that by performing polishing using the polishing composition of the present invention, a substrate having a polished surface with a smaller surface roughness (Ra) (that is, having excellent smoothness) is obtainable.

Incidentally, the present application is based on. Japanese Patent Application No. 2016-61554 filed on Mar. 25, 201.6, and a disclosed content thereof is incorporated herein as a whole by reference.

1. A polishing composition used for polishing an object to be polished having a metal-containing layer, the polishing composition comprising:
abrasive grains;
an acid;
an oxidizer; and
a dispersing medium,
wherein an acid dissociation constant (pKa) of the acid is higher than a pH of the composition.

2. The polishing composition according to claim 1, wherein the metal is tungsten.

3. The polishing composition according to claim 1, wherein a difference between the acid dissociation constant (pKa) of the acid and the pH of the composition [=(the acid dissociation constant (pKa) of the acid)−(the pH of the composition)] is 0.9 or more.

4. The polishing composition according to claim 1, wherein the acid dissociation constant (pKa) of the acid is 2.9 or more and less than 5.0.

5. The polishing composition according to claim 1, wherein the oxidizer is a peroxide.

6. The polishing composition according to claim 5, wherein the peroxide is at least one kind selected from the group consisting of hydrogen peroxide, peracetic acid, a percarbonate salt, urea peroxide, sodium persulfate, potassium persulfate, ammonium persulfate, potassium monopersulfate, and oxone.

7. The polishing composition according to claim 1, wherein the abrasive grains are colloidal silica having an organic acid immobilized.

8. A method for producing the polishing composition according to claim 1, the method comprising mixing the abrasive grains, the acid, and the oxidizer.

9. A polishing method comprising polishing an object to be polished having a metal-containing layer using the polishing composition according to claim 1.

10. A method for producing a substrate, the method comprising a process of polishing an object to be polished having a metal-containing layer by the polishing method according to claim 9.
